(19) United States
(12) Patent Application Publication
(10) Pub. No.: US 2025/0293536 A1
(43) Pub. Date: Sep. 18, 2025

(54) BATTERY CHARGE CONTROL OPTIMIZATION FOR EXTENDED LIFE WITH MACHINE

(71) Applicant: Caterpillar Inc., Peoria, IL (US)

(72) Inventors: Ted Gerhardt Rimstidt, West Lafayette, IN (US); Matthew Beckner, Chillicothe, IL (US); Jay Venkataraghavan, Dunlap, IL (US)

(73) Assignee: Caterpillar Inc., Peoria, IL (US)

(21) Appl. No.: 18/608,094

(22) Filed: Mar. 18, 2024

(51) Int. Cl. H02J 7/00; G06N 20/00

(52) U.S. Cl. CPC H02J 7/00712; G06N 20/00; H02J 7/005

(57) ABSTRACT

Techniques are described for using machine learning to extract physics-based cell model parameters from battery charge data provided by the battery module of the battery management system. This data may be processed via machine learning techniques in order to periodically update or adapt a physics-based model that may capture cell electrical dynamics and degradation mechanisms. The techniques may utilize a “digital twin” to adaptively charge the battery while preserving the life of the cells.

### FIELD OF THE DISCLOSURE

This document pertains generally, but not by way of limitation, to battery management systems and, more specifically, to methods and systems for optimizing the performance and extending the longevity of battery cells within a battery module.

### BACKGROUND

Rechargeable batteries, particularly Lithium-ion (Li-ion) batteries, have become the cornerstone of electric machine, including electric vehicle technology, offering a greener, more sustainable alternative to traditional fossil fuel-powered engines. These batteries boast high energy density, longer lifespans, and lower self-discharge rates, making them ideal for powering electric cars and heavy machinery. The efficiency and durability of these batteries are critical, as they directly impact the range, performance, and overall appeal of electric vehicles.

The charging algorithms for electric machines are crucial in optimizing battery health and performance. These sophisticated algorithms are designed to balance the need for fast charging against the potential risks of overcharging, which can degrade battery life and pose safety risks. Smart charging technologies in electric machines adjust charging rates based on the battery's condition, ambient temperature, and usage patterns. Some employ pulse charging methods, providing intermittent bursts of energy to enhance charge absorption and minimize heat generation, which is particularly important in large battery packs used in electric vehicles.

However, battery degradation remains a significant challenge. Over time, Li-ion batteries in electric vehicles undergo chemical and physical changes that reduce their capacity and efficiency. Factors such as the number of charge-discharge cycles, exposure to extreme temperatures, and high current demands during rapid acceleration and heavy load conditions contribute to this degradation. In electric vehicles, battery aging can lead to reduced driving range and slower charging times, impacting both the user experience and the vehicle's resale value.

### SUMMARY OF THE DISCLOSURE

This disclosure describes techniques for using machine learning to extract physics-based cell model parameters from battery charge data provided by the battery module of the battery management system. This data may be processed via machine learning techniques in order to periodically update or adapt a physics-based model that may capture cell electrical dynamics and degradation mechanisms. The techniques may utilize a “digital twin” to adaptively charge the battery while preserving the life of the cells.

In some aspects, this disclosure is directed to a battery management system for managing operation and health of a battery cell of a battery module, the battery management system comprising: a processing unit in communication with the battery module; and a non-transitory computer-readable memory in communication with the processing unit, the non-transitory computer-readable memory including instructions that, when executed, cause the processing unit to: simulate, using a physics-based model, electrochemical processes of the battery cell; receive, using a machine-learning model, operational data from the battery module and calibrate the physics-based model based on the received operational data; and control, based on the physics-based model, the operation of the battery module.

In some aspects, this disclosure is directed to a method for managing operation and health of a battery cell of a battery module, the method comprising: simulating, using a physics-based model, electrochemical processes of the battery cell; receiving, using a machine-learning model, operational data from the battery module and calibrating the physics-based model based on the received operational data; and controlling, based on the physics-based model, the operation of the battery module.

In some aspects, this disclosure is directed to a battery management system for managing operation and health of a battery cell of a battery module, the battery management system comprising: a plurality of sensors configured to sense operational data from the battery module, wherein the operational data includes at least one of temperature, voltage, current, state of charge, and state of health of the battery cell; a processing unit in communication with the battery module; and a non-transitory computer-readable memory in communication with the processing unit, the non-transitory computer-readable memory including instructions that, when executed, cause the processing unit to: simulate, using a physics-based model, electrochemical processes of the battery cell, wherein the physics-based model, once calibrated, serves as a digital twin of the battery cell, and wherein the digital twin provides a virtual representation that approximates real-time behavior of the battery cell; receive, using a machine-learning model, the operational data from the battery module and calibrate the physics-based model based on the received operational data; and control, based on the physics-based model, the operation of the battery module.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a perspective view of an example of a battery-powered machine that may implement various techniques of this disclosure.

FIG. 2 is a block diagram of an example of an electrical architecture that may implement various techniques of this disclosure.

FIG. 3 shows an example of a machine learning module according to some examples of the present disclosure.

FIG. 4 is a block diagram of another example of an electrical architecture that may implement various techniques of this disclosure.

FIG. 5 is a flow diagram of an example of a method for managing operation and health of a battery cell of a battery module.

### DETAILED DESCRIPTION

The management of battery systems, particularly in applications such as electric vehicles, energy storage systems, and portable electronics, presents a series of complex challenges. Traditional battery management systems often rely on direct physical monitoring and control mechanisms that may be limited in their ability to predict and adapt to the dynamic conditions affecting battery performance, longevity, and safety. These systems typically lack the capability to accurately forecast future states of the battery cells based on varying operational conditions, which can lead to suboptimal performance, reduced lifespan, and increased risk of failure. Current battery management system algorithms are typically based on static battery models designed for beginning of life conditions.

The present inventors recognized a need for an advanced battery management system capable of accurately predicting and optimizing the performance and lifespan of battery cells. This disclosure describes techniques for using machine learning to extract physics-based cell model parameters from battery charge data provided by the battery module of the battery management system. This data may be processed via machine learning techniques in order to periodically update or adapt a physics-based model that may capture cell electrical dynamics and degradation mechanisms. The techniques may utilize a “digital twin” to adaptively charge the battery while preserving the life of the cells.

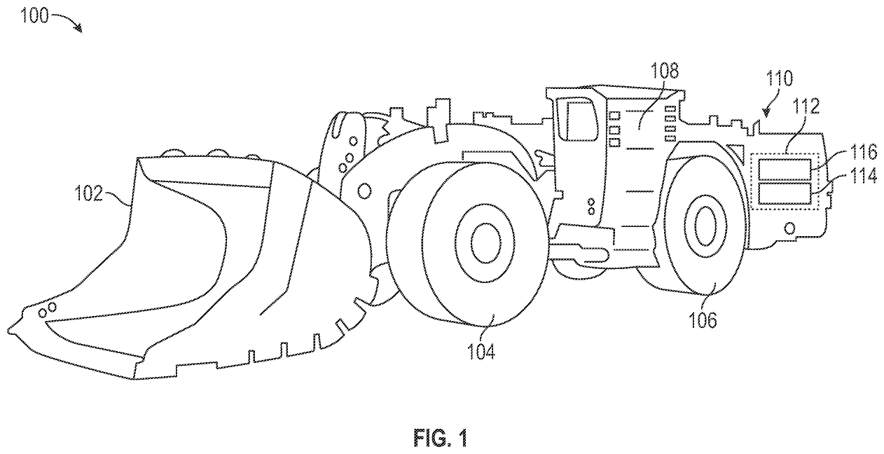

FIG. 1 is a perspective view of an example of a battery-powered machine 100 that may implement various techniques of this disclosure. FIG. 1 depicts a non-limiting view of a battery-powered machine 100 in the form of a load-haul-dump (LHD) vehicle, such as for mining, including a dump bucket 102, wheels 104, 106, an operator control cabin 108, and a vehicle body 110.

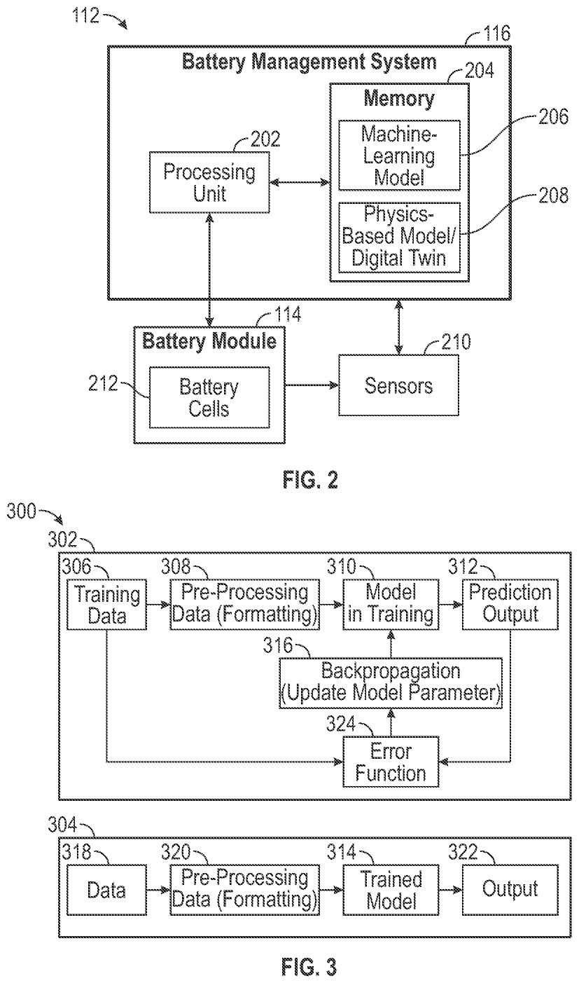

The battery-powered machine 100, e.g., an electric mine truck, also includes an electrical architecture 112. The electrical architecture 112 may include a DC power source, namely a battery module 114 having one or more battery cells, which may supply power to, among other things, an electric motor. The electric motor may supply rotational power to one or more systems, such as a system configured to operate various hydraulics of the dump bucket 102. The electrical architecture 112 further includes a battery management system 116 in communication with the battery module 114. The electrical architecture 112 is shown and described in more detail below, such as with respect to FIG. 2.

The techniques of this disclosure are not limited to LHD vehicles and are instead applicable to other industrial vehicles including, but not limited to, continuous miners, feeder breakers, roof bolters, utility vehicles for mining, underground mining loaders, underground articulated trucks, or any other vehicle used for industrial purposes, such as hauling, excavating, drilling, loading, dumping, compacting, etc. Further, the techniques of this disclosure, while especially suited for use in battery-powered vehicles, also may be used in hybrid-powered vehicles.

FIG. 2 is a block diagram of an example of an electrical architecture that may implement various techniques of this disclosure. The electrical architecture 112 includes a battery module 114 in electrical communication with the battery management system 116. The battery module 114 includes a plurality of battery cells 212.

The battery management system (BMS) 116 further includes a processing unit 202, which includes one or more processors. The processing unit 202 may be in communication with a non-transitory computer-readable memory 204. In some examples, the processing unit 202 may be co-located with the battery module 114. In other examples, the processing unit 202 may be located remotely be configured to communicate with the battery module and the non-transitory computer-readable memory via a wireless communication network, such as shown in FIG. 3.

The memory 204 includes a machine-learning model 206 and a physics-based model/digital twin 208. The electrical architecture 112 may include a plurality of sensors 210 that are in electrical communication with the battery module 114 and the battery management system 116. Each sensor is configured to collect operational data from the battery module. For example, the operational data includes at least one of temperature, voltage, current, state of charge, and state of health of one or more of the battery cells 212. The state of charge (SOC) of battery cells 212 in a battery module 114 may be defined as the available capacity (in Ah) and expressed as a percentage of its rated capacity.

The SOC parameter may be viewed as a thermodynamic quantity enabling one to assess the potential energy of a battery. The SOC parameter of a battery decreases over time as energy is drawn from the battery. The state of health (SOH) of a battery cell represents a measure of the battery cell's ability to store and deliver electrical energy compared with a new battery. A decline in the SOH of a battery can cause a battery to discharge faster. A battery's internal impedance is an example of a battery characteristic that corresponds well with its SOH and that can be measured periodically to monitor the battery.

The physics-based model 208 may be a reduced-order model that serves to effectively approximate the comprehensive physical and chemical behaviors of one or more of the battery cells 212. This model is engineered to simplify the complex array of differential equations typically found in a full-scale physics-based model, which may include second or first-order partial differential equations (PDEs), by reducing them to first-order ordinary differential equations (ODEs) or to algebraic equations that are more computationally efficient.

The reduced-order physics-based model 208 approximates the governing physics/chemistry of the cell, such as the electrochemical processes and degradation mechanisms pertinent to the battery cell's operation. These processes include, but are not limited to, ion diffusion as governed by Fick's laws of diffusion, the intercalation reaction of lithium ions with the electrode particles as described by Butler-Volmer kinetics, the formation of a solid electrolyte interphase (SEI) layer, and the plating of lithium on the anode surface. The model is designed to account for any additional degradation mechanisms that may impact the battery cell's performance and longevity.

While comprehensive full-physics models, such as the single particle model (SPM) and the pseudo-two-dimensional model (P2D), provide a detailed representation of the battery cell's behavior, their direct implementation within a battery management system (BMS) may be impractical due to the substantial computational resources they require. The reduced-order model may be a pragmatic solution that delivers a balance between computational simplicity and the retention of essential physical and chemical characteristics, thereby enabling real-time analysis and management of the battery within the computational constraints of the BMS.

The machine-learning model 206 is an analytical tool that uses data-driven algorithms to enhance the predictive accuracy and operational efficiency of the battery management system 116. Utilizing historical and/or real-time data from the battery module 114 collected by the sensors 210, the machine-learning model 206 is trained to identify complex patterns and correlations that are not readily discernible through traditional analysis methods. The machine-learning model 206 continuously refines its predictive capabilities through adaptive learning, enabling it to forecast future battery states, such as the state of charge and/or the state of health, with a high degree of precision. The machine learning machine-learning model 206 also contributes to the optimization of charging and discharging cycles, the anticipation of potential failure modes, and the formulation of maintenance schedules, thereby improving the overall reliability, safety, and lifespan of the battery. By integrating this model, the battery management system 116 is equipped to make informed decisions, dynamically adjust operational parameters in response to changing conditions, and provide actionable insights to maintain the battery at its optimal performance level.

In some examples, the machine-learning model 206 is configured to calibrate the physics-based model 208 using the operational data collected by the plurality of sensors. For example, the machine-learning model 206 adjusts various parameters of the physics-based model to align its predictions more closely with the observed data. This calibration process may involve fine-tuning variables within the physics-based model, such as reaction rates, diffusion coefficients, or state variables, to correct for any deviations and improve the model's fidelity. The calibrated physics-based model 208 is thus a refined representation of the battery cell's behavior, offering improved accuracy in simulating the battery cell's performance. In some examples, the machine-learning model 206 is configured to update the calibration of the physics-based model 208 over the life of the battery cell to account for aging and changes in battery cell performance.

The physics-based model 208, once calibrated, serves as a digital twin of the battery cell, where the digital twin provides a virtual representation that approximates the real-time behavior of the battery cell. A digital twin refers to a comprehensive digital representation that simulates the physical state and dynamics of the battery cell, reflecting its current condition and performance. The calibrated physics-based model, as a digital twin, incorporates a multitude of parameters and variables that characterize the battery cell, including but not limited to electrochemical properties, thermal behavior, and electrical performance. By simulating these aspects, the digital twin provides insights into the battery cell's functionality under various load conditions, state of charge (SoC) levels, and environmental influences.

The digital twin is configured to simulate and predict future performance and degradation of the battery cell under various operating conditions. The digital twin enables predictive analytics and diagnostics by forecasting the battery's future states and identifying potential issues before they manifest in the physical cell. The digital twin allows the processing unit 202 to perform a scenario analysis, where different operational strategies can be virtually tested on the digital twin to assess their impact on the battery's performance and longevity without risking damage to the actual battery cells 212.

Moreover, the digital twin serves as a decision-support tool for the battery management system 116, facilitating optimized charge and discharge cycles, maintenance planning, and end-of-life assessments. The digital twin acts as a bridge between the physical and digital domains, enabling a continuous feedback loop where data from the physical battery cells 212 informs the digital twin, and the insights from the digital twin guide the management of the physical battery cells 212. In particular, in some examples, the machine-learning model 206 is configured to update the digital twin in real time to reflect changes in at least one of the state of charge and the state of health of the battery cell.

The digital twin's ability to provide a real-time virtual representation of the battery cell's state and behavior is important in enhancing the operational efficiency, safety, and reliability of the battery management system 116. The digital twin is a dynamic model that evolves with the battery cell over time, capturing the effects of aging and wear, thus ensuring that the virtual representation remains an accurate reflection of the physical battery throughout its lifecycle.

Using various techniques of this disclosure, the battery management system 116 simulates, using the physics-based model 208, the electrochemical processes of the battery cell, e.g., one or more of the battery cells 212. Then, the machine-learning model 206 receives operational data of one or more of the battery cells 212 from the battery module and calibrates the physics-based model 208 based on the received data. The processing unit 202 then controls, based on the physics-based model 208, the operation of the battery module 114.

In some examples, the processing unit 202 is configured to adjust operational parameters of the battery module 114 in real time based on the calibrated physics-based model to enhance battery cell performance and longevity. The operational parameters that the processing unit may adjust include, but are not limited to, charge and discharge rates, voltage thresholds, temperature setpoints, and balancing strategies. By continuously monitoring the battery cell's state through the digital twin and comparing it against the desired performance criteria, the processing unit 202 may make informed decisions to modify these parameters. For example, if the digital twin predicts an impending thermal event, the processing unit 202 may preemptively lower the charge rate to mitigate the risk.

The adjustments made by the processing unit 202 are based on a complex interplay of data, including current SoC, SoH, usage patterns, and environmental conditions. The calibrated physics-based model provides a predictive framework that enables the processing unit 202 to anticipate the battery cell's response to various operational scenarios. This foresight allows for the implementation of proactive measures that may prevent stress on the battery cell, thereby reducing the likelihood of degradation and failure.

Furthermore, the processing unit's real-time adjustments may facilitate adaptive energy management, ensuring that the battery module 114 operates within its optimal efficiency range. This not only enhances the immediate performance of the battery cell but also contributes to its long-term health by avoiding conditions that could accelerate wear and aging.

The processing unit's capability to adjust operational parameters in real time, guided by the calibrated physics-based model, represents a significant advancement in battery management technology. It embodies a proactive approach to battery maintenance, where the BMS actively shapes the battery's operational environment to promote peak performance and maximize lifespan, rather than merely reacting to adverse conditions after they arise.

In some examples, the battery management system 116 reads operational data from the sensors 210. The processing unit 202 calculates one or more state of charge, state of health, and state of function (SoF) of one or more of the battery cells 212. The machine-learning model 206 receives the sensor data, which may be used for training the model.

The physics-based model/digital twin 208 may periodically trigger an update by the machine-learning model 206 at a specified learning rate. The physics-based model/digital twin 208 may calculate a degradation rate of the battery cells 212 based on the received data from the sensors 210 and the onboard physics-based model/digital twin 208. In addition, the physics-based model/digital twin 208 SoF limit flags may be sent back to the processing unit 202 to apply additional limits to battery module 114 current to stay under degradation rate limits, e.g., derate the limits.

FIG. 3 describes an example of a process of training a machine learning model to produce a trained machine learning model, such as the machine learning model 206 of FIG. 2.

The machine learning module 300 may be implemented in whole or in part by one or more computing devices. In some examples, a training module 302 may be implemented by a different device than a prediction module 304. In these examples, the trained model 314 may be created on a first machine and then sent to a second machine. For example, the training may be performed in a server device, e.g., “in the cloud”, and then the trained model may be sent to another device, such as a PC.

The machine learning module 300 utilizes a training module 302 and a prediction module 304. The training data 306 may be formatted using a pre-processing module 308. The training data 306 may include, for example, using historical and real-time data collected by the sensors 210 of FIG. 2. In some implementations, the training data 306 may include at least some simulation training data. In some examples, simulated and experimental data may be included in the training data 306 set prior to the model training.

During training, the training module 302 may compare the training data 306 and the prediction output 312 and generate an error function 324 based on the comparison. In some examples, the training module 302 may update the machine learning model in training 310 in response to the error function 324, such as by using backpropagation module 316.

In the prediction module 304, the data 318 may be input and pre-processed using a pre-processing module 320 to format the data prior to sending to the trained model 314. The pre-processing module 320 generates formatted data, which is input into the trained model 314 to generate an output 322. In some implementations, the pre-processing module 308 and the pre-processing module 320 may be the same module.

The machine learning model in training 310 may be selected from among many different potential supervised or unsupervised machine learning algorithms. Examples of learning algorithms include artificial neural networks, convolutional neural networks, Bayesian networks, instance-based learning, support vector machines, decision trees (e.g., Iterative Dichotomiser 3, C4.5, Classification and Regression Tree (CART), Chi-squared Automatic Interaction Detector (CHAID), and the like), random forests, linear classifiers, quadratic classifiers, k-nearest neighbor, linear regression, logistic regression, a region based CNN, a full CNN (for semantic segmentation), a mask R-CNN algorithm for instance segmentation, and hidden Markov models. Examples of unsupervised learning algorithms include expectation-maximization algorithms, vector quantization, and information bottleneck method.

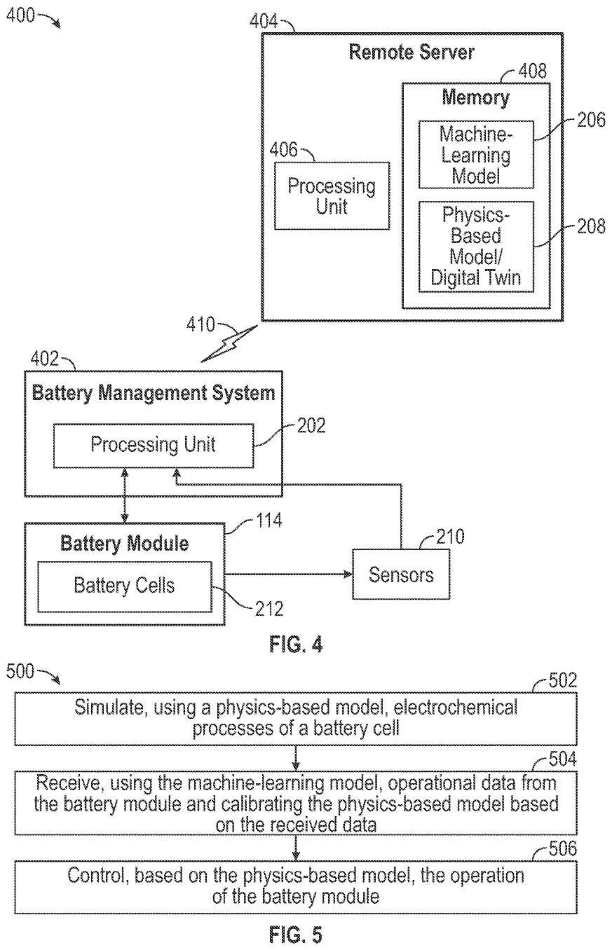

FIG. 4 is a block diagram of another example of an electrical architecture that may implement various techniques of this disclosure. The electrical architecture 400 includes a battery module 114 in electrical communication with a battery management system 402. The battery module 114 includes a plurality of battery cells 212. FIG. 4 includes features that are similar to those shown and described above with respect to FIG. 2 and similar reference numbers are used for such features. For brevity, those features will not be described again in detail.

In the example shown in FIG. 4, the electrical architecture 400 includes a remotely located remote server 404, e.g., a cloud platform, such as MICROSOFT AZURE® and AMAZON EC2®. The remote server 404 includes a processing unit 406 and memory 408, where the processing unit 406 is configured to communicate with the battery module 114 via a wireless communication network 410. The machine-learning model 206 and the physics-based model/digital twin 208 are stored on the remote server 404.

In some examples, the battery management system 116 reads operational data from the sensors 210. The processing unit 202 calculates one or more state of charge, state of health, and state of function (SoF) of one or more of the battery cells 212. The battery management system 116 then transmits the data from the sensors 210, including the calculated state of charge, state of health, and/or state of of function, to the remote server. The machine-learning model 206 receives the sensor data, which may be used for training the model.

The physics-based model/digital twin 208 may periodically trigger an update by the machine-learning model 206 at a specified learning rate. The physics-based model/digital twin 208 may calculate a degradation rate of the battery cells 212 based on the received data from the sensors 210 and the onboard physics-based model/digital twin 208. In addition, the physics-based model/digital twin 208 SoF limit flags may be sent back to the battery management system 116 to apply additional limits to battery module 114 current to stay under degradation rate limits, e.g., derate the limits.

FIG. 5 illustrates a flow diagram of an example of a method 500 for managing operation and health of a battery cell of a battery module. At block 502, the method 500 includes simulating, using the physics-based model, electrochemical processes of the battery cell.

At block 504, the method 500 includes receiving, using the machine-learning model, operational data from the battery module and calibrating the physics-based model based on the received data.

At block 506, the method 500 includes controlling, based on the physics-based model, the operation of the battery module.

In some examples, the method 500 includes sensing the operational data from the battery module, wherein the operational data includes at least one of temperature, voltage, current, state of charge, and state of health of the battery cell.

In some examples, the method 500 includes calibrating the physics-based model using the operational data collected by the plurality of sensors.

In some examples, the method 500 includes updating the calibration of the physics-based model over the life of the battery cell.

In some examples, the method 500 includes providing, as a digital twin, a virtual representation that approximates the real-time behavior of the battery cell.

In some examples, the method 500 includes storing the digital twin on a remote server.

In some examples, the method 500 includes training the machine-learning model using historical and real-time data collected by a plurality of sensors.

### INDUSTRIAL APPLICABILITY

The present invention has significant industrial applicability, offering substantial improvements in the management and operation of battery systems across various sectors. The integration of a digital twin with a physics-based reduced order model (ROM) and machine learning algorithms within a battery management system (BMS) provides a robust solution that is particularly beneficial for industries where battery reliability, efficiency, and longevity are critical.

For example, with electric machines as well as electric vehicles (EVs), the techniques of this disclosure may be used to enhance the performance and safety of lithium-ion batteries. By accurately predicting the State-of-Charge (SOC), State-of-Health (SOH), and State-of-Function (SOF), the BMS ensures optimal charging strategies, prevents over-discharge, and extends the overall life of the battery, thereby reducing the total cost of ownership and improving the user experience.

In addition, the renewable energy sector, which relies heavily on battery storage systems to manage intermittent power sources such as wind and solar, stands to benefit from the invention's predictive maintenance capabilities. The digital twin enables energy operators to anticipate and address potential battery failures before they occur, ensuring a consistent and reliable energy supply and reducing downtime.

In summary, the invention's industrial applicability is broad and impactful, offering enhanced battery management solutions that can be tailored to the specific needs of various industries. By improving battery performance, extending battery life, and ensuring safety, the invention provides a competitive advantage to manufacturers and operators of battery systems, contributing to the advancement of energy storage technology.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A battery management system for managing operation and health of a battery cell of a battery module, the battery management system comprising:
a processing unit in communication with the battery module; and
a non-transitory computer-readable memory in communication with the processing unit, the non-transitory computer-readable memory including instructions that, when executed, cause the processing unit to:
simulate, using a physics-based model, electrochemical processes of the battery cell;
receive, using a machine-learning model, operational data from the battery module and calibrate the physics-based model based on the received operational data; and
control, based on the physics-based model, the operation of the battery module.

2. The battery management system of claim 1, comprising:
a plurality of sensors configured to sense the operational data from the battery module, wherein the operational data includes at least one of temperature, voltage, current, state of charge, and state of health of the battery cell.

3. The battery management system of claim 2, wherein the machine-learning model is configured to calibrate the physics-based model using the operational data collected by the plurality of sensors.

4. The battery management system of claim 3, wherein the machine-learning model is configured to update the calibration of the physics-based model over a life of the battery cell.

5. The battery management system of claim 3, wherein the physics-based model, once calibrated, serves as a digital twin of the battery cell, and wherein the digital twin provides a virtual representation that approximates real-time behavior of the battery cell.

6. The battery management system of claim 5, wherein the digital twin is stored on a remote server.

7. The battery management system of claim 5, wherein the digital twin is configured to simulate and predict future performance and degradation of the battery cell.

8. The battery management system of claim 5, wherein the machine-learning model is configured to update the digital twin in real-time to reflect changes in at least one of the state of charge and the state of health of the battery cell.

9. The battery management system of claim 2, wherein the machine-learning model is trained using historical and real-time data collected by the plurality of sensors.

10. The battery management system of claim 2, wherein the processing unit is configured to adjust one or more operational parameters of the battery module in real time based on the calibrated physics-based model.

11. The battery management system of claim 2, wherein the processing unit is located remotely and is configured to communicate with the battery module via a wireless communication network.

12. A method for managing operation and health of a battery cell of a battery module, the method comprising:
simulating, using a physics-based model, electrochemical processes of the battery cell;
receiving, using a machine-learning model, operational data from the battery module and calibrating the physics-based model based on the received operational data; and
controlling, based on the physics-based model, the operation of the battery module.

13. The method of claim 12, comprising:
sensing the operational data from the battery module, wherein the operational data includes at least one of temperature, voltage, current, state of charge, and state of health of the battery cell.

14. The method of claim 13, comprising:
calibrating the physics-based model using the operational data collected by a plurality of sensors.

15. The method of claim 14, comprising:
updating the calibration of the physics-based model over a life of the battery cell.

16. The method of claim 13, comprising:
providing, as a digital twin, a virtual representation that approximates real-time behavior of the battery cell.

17. The method of claim 16, comprising:
storing the digital twin on a remote server.

18. The method of claim 16, comprising:
training the machine-learning model using historical and real-time data collected by a plurality of sensors.

19. A battery management system for managing operation and health of a battery cell of a battery module, the battery management system comprising:
a plurality of sensors configured to sense operational data from the battery module, wherein the operational data includes at least one of temperature, voltage, current, state of charge, and state of health of the battery cell;
a processing unit in communication with the battery module; and
a non-transitory computer-readable memory in communication with the processing unit, the non-transitory computer-readable memory including instructions that, when executed, cause the processing unit to:
simulate, using a physics-based model, electrochemical processes of the battery cell, wherein the physics-based model, once calibrated, serves as a digital twin of the battery cell, and wherein the digital twin provides a virtual representation that approximates real-time behavior of the battery cell;
receive, using a machine-learning model, the operational data from the battery module and calibrate the physics-based model based on the received operational data; and
control, based on the physics-based model, the operation of the battery module.

20. The battery management system of claim 19, wherein the digital twin is configured to simulate and predict future performance and degradation of the battery cell.
